(19) United States
(12) Patent Application Publication
(10) Pub. No.: US 2026/0072231 A1
(43) Pub. Date: Mar. 12, 2026

(54) Electronic Devices with Display Supports

(71) Applicant: Apple Inc., Cupertino, CA (US)

(72) Inventors: James A Stryker, Campbell, CA (US); Wei Lv, San Jose, CA (US); Sijun Niu, Santa Clara, CA (US); Wenyong Zhu, Saratoga, CA (US); Adam T Garelli, Morgan Hill, CA (US); Peter Riering-Czekalla, Oakland, CA (US); Markus Diebel, San Francisco, CA (US)

(21) Appl. No.: 19/280,001

(22) Filed: Jul. 24, 2025

Related U.S. Application Data
(60) Provisional application No. 63/694,062, filed on Sep. 12, 2024.

(51) Int. Cl. G02B 7/02; H05K 5/02

(52) U.S. Cl. CPC G02B 7/02; H05K 5/0217

(57) ABSTRACT

An electronic device may include a display, such as flexible display. A display cover layer may overlap display layers in the display. The display may have an active area and an inactive area. A stiffener may support the cover layer in the inactive area, and an endcap may be coupled to the display cover layer in the inactive area. The endcap may be separated from the display layers by a gap. The stiffener may be a metal stiffener, or may be a thickened portion of the cover layer. The stiffener may include openings to form windows for optical components.

Lenses may be coupled to the stiffener and/or the cover layer in the openings. Trim may be interposed between an edge of the cover layer and a device housing, and the edge of the cover layer may be separated from the trim by a gap.

This application claims the benefit of U.S. provisional patent application No. 63/694,062 , filed Sep. 12, 2024, which is hereby incorporated by reference herein in its entirety.

### FIELD

This relates generally to electronic devices, including electronic devices with displays.

### BACKGROUND

Electronic devices often include displays for presenting images to a user. Displays may have one or more flexible display layers.

### SUMMARY

An electronic device may include a display, such as a flexible display with a first portion, a second portion that is aligned with a bend axis, and a third portion. The second portion may be interposed between the first and third portions, the first portion may be configured to bend relative to the third portion about the bend axis, and the flexible display may have a periphery. The display may include display layers and a cover layer that overlaps the display layers.

The display may have an active area and an inactive area. A stiffener may support the cover layer in the inactive area, and an endcap may be coupled to the display cover layer in the inactive area. The endcap may be separated from the display layers by a gap, and the stiffener may extend across the gap. The endcap may support the display cover layer in regions of the inactive area.

The stiffener may be a rigid stiffener, such as a metal stiffener, or may be a thickened portion of the cover layer. The stiffener may include openings to form windows for optical components in the inactive area. Lenses may be coupled to the stiffener and/or the cover layer in the openings. Trim may be interposed between an edge of the cover layer and a device housing, and the edge of the cover layer may be separated from the trim by a gap.

### BRIEF DESCRIPTION OF THE DRAWINGS

FIG. 1 is a perspective view of an illustrative electronic device having a display in accordance with some embodiments.

FIG. 2 is a schematic diagram of an illustrative electronic device having a display in accordance with some embodiments.

FIG. 3 is a perspective view of an illustrative electronic device having a display with an array of pixels in accordance with some embodiments.

FIGS. 4 and 5 are side views of electronic devices with flexible displays in accordance with some embodiments.

FIG. 6 is a front view of an illustrative electronic device having a display with different inactive area regions in accordance with some embodiments.

FIG. 7A is a perspective view of an illustrative electronic device with a display cover layer that is supported by display layers in a first inactive area region and by an endcap attached to the display layers in a second inactive area region in accordance with some embodiments.

FIG. 7B is a perspective view of an illustrative electronic device with a display cover layer that is supported by display layers in a first inactive area region and by an endcap attached to a housing in a second inactive area region in accordance with some embodiments.

FIG. 8 is a side view of an illustrative electronic device including an endcap that supports a display cover layer in accordance with some embodiments.

FIG. 9 is a side view of an illustrative electronic device including a stiffener that supports a display cover layer in accordance with some embodiments.

FIG. 10 is a side view of an illustrative electronic device including a stiffener and an endcap that support a display cover layer in accordance with some embodiments.

FIG. 11 is a side view of an illustrative electronic device including a wedge-shaped stiffener that supports a display cover layer in accordance with some embodiments.

FIG. 12 is a side view of an illustrative electronic device with a wedge-shaped display cover layer with a planar outer surface in accordance with some embodiments.

FIG. 13 is a side view of an illustrative electronic device with a wedge-shaped display cover layer with a planar inner surface in accordance with some embodiments.

FIGS. 14A and 14B are side views of an illustrative electronic device with a display cover layer that is thinner at a bend axis than at a periphery of the device in accordance with some embodiments.

FIG. 15 is a front view of an illustrative electronic device having a display with an active area, an opaque masking region, and a trim in accordance with some embodiments.

FIG. 16 is a side view of an illustrative electronic device including a stiffener that supports a display cover layer and that has an optical component window opening in accordance with some embodiments.

### DETAILED DESCRIPTION

Electronic devices may include displays, such as flexible displays. For example, an electronic device may be bendable/foldable, and a flexible display may allow the electronic device to bend/fold. The flexible display may include a cover layer (e.g., a flexible display cover layer). The cover layer may extend over an active area and an inactive area of the flexible display.

In some portions of the inactive area, the cover layer may be supported by underlying display layers that also extend into the inactive area. However, in other portions of the inactive area, the flexible display may have display interconnects (e.g., printed circuits) that wrap around an edge of the flexible display. In these panel bend portions, the underlying display layers may be blocked from extending into the inactive area due to the display interconnects.

Therefore, to support the cover layer in these panel bend portions, an endcap may be attached to the extended display layers in an adjacent portion of the inactive area. The endcap may include the same display layers as the flexible display or may include an elastomer with a similar shear stiffness as the display layers.

Alternatively or additionally, a stiffener may be used in the panel bend portions. The stiffener may be a metal stiffener that is coupled to the cover layer in the panel bend portions, may be a thicker portion of the cover layer in the panel bend portions, or may be any other suitable stiffener. One or more openings may be formed in the stiffener to form window(s) for underlying optical components.

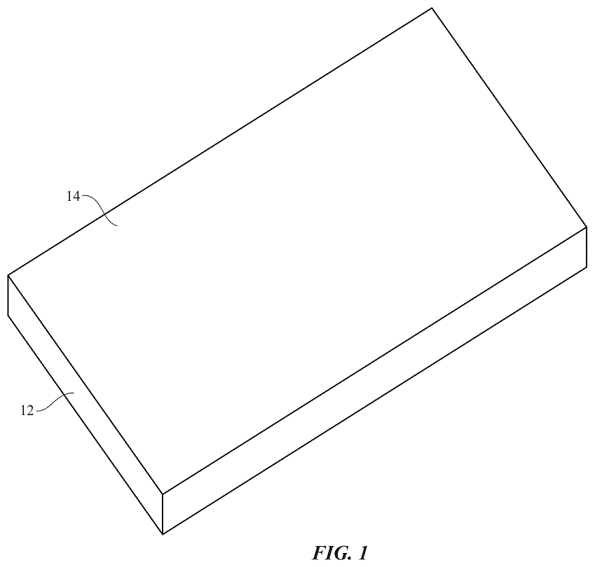

An illustrative electronic device of the type that may be provided with a flexible display is shown in FIG. 1. Electronic device 10 may be a computing device such as a laptop computer, a computer monitor containing an embedded computer, a tablet computer, a cellular telephone, a media player, or other handheld or portable electronic device, a smaller device such as a wrist-watch device, a pendant device, a wearable or miniature device of other types, a computer display that does not contain an embedded computer, a computer display that includes an embedded computer, a gaming device, a navigation device, a head-mounted device, an embedded system such as a system in which electronic equipment with a display is mounted in a kiosk or automobile, equipment that implements the functionality of two or more of these devices, or other electronic equipment. In the illustrative configuration of FIG. 1, device 10 is a portable device such as a cellular telephone, media player, tablet computer, watch or other wrist device, or other portable computing device. Other configurations may be used for device 10 if desired. The example of FIG. 1 is merely illustrative.

In the example of FIG. 1, device 10 includes a display such as display 14 mounted in housing 12. Housing 12, which may sometimes be referred to as an enclosure or case, may be formed of plastic, glass, ceramics, fiber composites, metal (e.g., stainless steel, aluminum, etc.), other suitable materials, or a combination of any two or more of these materials. Housing 12 may be formed using a unibody configuration in which some or all of housing 12 is machined or molded as a single structure or may be formed using multiple structures (e.g., an internal frame structure, one or more structures that form exterior housing surfaces, etc.). Portions of housing 12 may be formed from flexible materials (e.g., elastomeric materials such as silicone and/or other flexible polymers) and/or may include hinge structures.

Housing 12 may have a hinge at axis to allow device 10 to bend. The hinge may include one or more hinge mechanisms, such as pivoting structures, single-bar or multibar linkages and/or other hinging mechanisms. Using these hinge mechanisms, housing 12 may bend about the bend axis (sometimes referred to as a bending axis, fold axis, folding axis, flex axis, etc.). Housing 12 may have first and second housing portions that rotate with respect to each other as device 10 is bent (folded) about the bend axis using the hinge and/or other flexible structures joining the first and second housing portions.

Display 14 may be a touch screen display that incorporates a layer of conductive capacitive touch sensor electrodes or other touch sensor components (e.g., resistive touch sensor components, acoustic touch sensor components, force-based touch sensor components, light-based touch sensor components, etc.) or may be a display that is not touch-sensitive. Capacitive touch screen electrodes may be formed from an array of indium tin oxide pads or other transparent conductive structures. A touch sensor may be formed using electrodes or other structures on a display layer that contains a pixel array or on a separate touch panel layer that is attached to the pixel array (e.g., using adhesive).

Display 14 may include pixels formed from liquid crystal display (LCD) components, electrophoretic pixels, microelectromechanical (MEMs) shutter pixels, electrowetting pixels, micro-light-emitting diodes (e.g., small crystalline semiconductor die), organic light-emitting diodes (e.g., pixels in a thin-film organic light-emitting diode display), or pixels based on other display technologies. Configurations in which display 14 has an array of light-emitting pixels such as an array of organic light-emitting diode pixels may sometimes be described herein as an example.

Display 14 may a portion that overlaps the bend axis. To facilitate bending of device 10 about the bend axis, all of display 14 may be formed using flexible structures or at least the portion of display 14 that overlaps the bend axis may be formed using flexible structures. A display cover layer or other layer may form the outermost surface of the display. Display layers such these (e.g., display cover layers) may be formed from glass, plastic, and/or other transparent display cover layer structures and may be flexible (at least where these layers overlap the bend axis of device 10). In other words, the display cover layer may be a flexible display cover layer.

As shown in FIG. 1, for example, display 14 may have three portions. In particular, a left portion of display 14 may overlap a left portion of housing 12, a right portion of display 14 a right portion of housing 12, and a central portion of display 14 may overlap a bend region of housing 12 that is aligned with the bend axis. In the portions that the left and right portions of housing 12, display 14 may be flexible or may be rigid (e.g., the pixel array in these areas may be rigid and/or the display cover layer structures in these regions may be rigid). The portion of display 14 that overlaps the bend axis may form a strip that lies between the portions of display 14 that overlap the left and right portions of housing 12 and may extend across the width of the display between opposing edges of the display. To ensure the portion of display 14 that overlaps the bend axis is sufficiently flexible to allow device 10 to bend about the bend axis, display layers such as a display cover layer for display 14 may be formed from a thin flexible glass or polymer layer that accommodates bending of display 14 about the bend axis and underlying display layers (e.g., a polymer substrate, metal traces, a polarizer layer, a touch sensor layer, adhesive layers, and other conducting and dielectric layers in an organic light-emitting diode pixel array) may also be formed from flexible materials and structures.

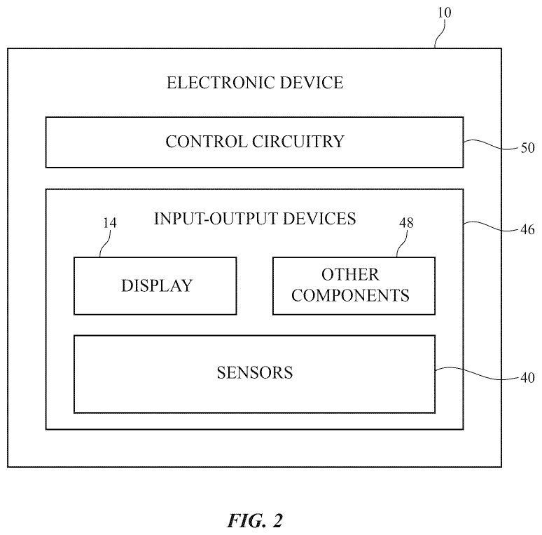

A schematic diagram of an illustrative electronic device such as device 10 of FIG. 1 is shown in FIG. 2. As shown in FIG. 2, electronic device 10 may have control circuitry 50.

Control circuitry 50 may include storage and processing circuitry for supporting the operation of device 10. The storage and processing circuitry may include storage such as hard disk drive storage, nonvolatile memory (e.g., flash memory or other electrically-programmable-read-only memory configured to form a solid state drive), volatile memory (e.g., static or dynamic random-access-memory), etc. Processing circuitry in control circuitry 50 may be used to control the operation of device 10 (e.g., to process sensor signals and other input and to control adjustable components such as a display, a heating element, etc.). The processing circuitry may be based on one or more microprocessors, microcontrollers, digital signal processors, baseband processors, power management units, audio chips, application specific integrated circuits, etc.

Input-output devices in device 10 such as input-output devices 46 may be used to allow data to be supplied to device 10 and to allow data to be provided from device 10 to external devices. As shown in FIG. 2, input-output devices 46 may include display 14. Display 14 may be a touch screen that incorporates a two-dimensional touch sensor or may be insensitive to touch. A two-dimensional touch sensor for display 14 may be formed from an array of capacitive touch electrodes touch sensor or other touch sensor components (e.g., force sensors, resistive touch sensors, acoustic touch sensors, optical sensors, etc.).

Input-output devices 46 may include sensors 40. Sensors 40 may include a capacitive proximity sensor, a light-based proximity sensor, a magnetic sensor, a force sensor such as a force sensor that gathers user input, a touch sensor for gathering user touch input, a temperature sensor, a pressure sensor, an ambient light sensor, a microphone or other sound sensor that gathers ambient noise measurements and user input such as voice commands, sensors for gathering data on device position and motion such as inertial measurement units that include accelerometers, compasses, and/or gyroscopes, one or more of any desired number of these sensors, and/or other sensors.

Input-output devices 46 may also include other components 48 such as buttons, joysticks, scrolling wheels, touch pads, key pads, keyboards, speakers, tone generators, vibrators (sometimes referred to as haptic output devices), cameras, light-emitting diodes and other status indicators, data ports, etc. A user can control the operation of device 10 by supplying user input commands through input-output devices 46 and may receive status information and other output from device 10 using the output resources of input-output devices 46.

Control circuitry 50 may be used to run software on device 10 such as operating system code and applications. During operation of device 10, the software running on control circuitry 50 may display images on display 14 (e.g., video, still images such as text, alphanumeric labels, photographs, icons, other graphics, etc.) using an array of pixels in display 14.

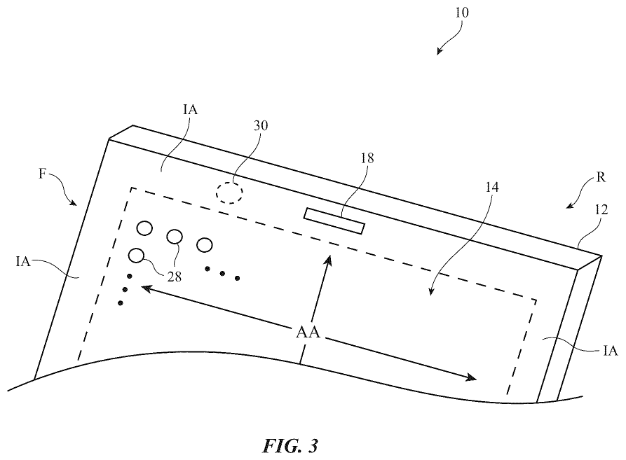

A perspective view of a portion of an illustrative electronic device that may include a flexible display is shown in FIG. 3. In the example of FIG. 3, device 10 includes a display such as display 14 mounted in housing 12.

Openings may be formed in device 10. For example, an opening may be formed in display 14 to accommodate a button, a speaker port such as illustrative speaker port 18 of FIG. 3, and/or other components. Openings may be formed in housing 12 to form communications ports (e.g., an audio jack port, a digital data port, etc.), to form openings for buttons, openings for microphones and speakers, etc.

Display 14 may be a liquid crystal display, an electrophoretic display, an organic light-emitting diode display or other display with an array of light-emitting diodes, a plasma display, an electrowetting display, a microLED display, a display based on microelectromechanical systems (MEMs) pixels, or any other suitable display. Display 14 may have an array of pixels 28 in active area AA. Pixels 28 of active area AA may display images for a user of device 10. Active area AA may be rectangular or may have other suitable shapes. In some configurations, display 14 may have a flexible polymer substrate such as a polyimide substrate on which an array of pixel structures such as an array of organic light-emitting diodes and associated pixel circuits is formed. The flexible polymer substrate may facilitate bending. However, the use of a flexible polymer substrate to allow bending is merely illustrative. In general, display 14 may be a folding display with any suitable flexible display substrate.

Inactive border area IA (also referred to as inactive area IA herein) may run along one or more edges of active area AA. Inactive border area IA may contain circuits, signal lines, and other structures that do not emit light for forming images. Masking structures (e.g., layers of black ink, etc.) may be used to hide inactive circuitry and other components in inactive area IA from view by a user of device 10. However, the inclusion of inactive area IA is merely illustrative. In some embodiments, device 10 may not include an inactive area, such as inactive area IA around the edges of active area AA. For example, active area AA extend between opposing edges of device 10 and/or extend entirely across (or across nearly an entirety of) a front face of device 10.

In some arrangements, inactive area IA may protrude into the active area AA and/or may form one or more isolated islands of inactive area within active area AA. Input-output components such as cameras, ambient light sensors, infrared depth sensors, light emitters (e.g., visible light emitters such as a camera flash, infrared light emitters that emit a pattern of infrared light for depth measurements, etc.), proximity sensors, speakers, microphones, and/or other input-output components may be accommodated by the protruding portions or islands of inactive area. Accommodating input-outputs in protruding portions or islands of inactive area within the active area may expand the available active area for displaying images.

Light-based components in device 10 (e.g., light-emitting diodes for status indicator lights and camera flashes, light-based sensors, and/or other optical components) may be overlapped by one or more windows such as window 30 of FIG. 3. Windows such as window 30 may be formed in a transparent portion of display 14 (e.g., a portion of inactive area IA), may be formed from a through-hole that passes through an array of pixels in display 14 (e.g., in an active area of display 14), and/or may be formed from transparent members of glass, sapphire, etc. that are mounted in housing 12 (e.g., in a rear housing wall of housing 12, etc.). In some configurations, thin layers of masking structures (e.g., thin black ink layers) may overlap optical windows that are otherwise transparent (e.g., to help obscure an optical component such as an ambient light sensor from view). In such configurations, light transmission may be reduced, but sufficient light is still passed to allow the optical window with the thin ink coating to serve as an optical window for an optical component (e.g., an ambient light sensor in this example).

In some configurations, device 10 may have front and rear surfaces such as front surface F and rear surface R of FIG. 3. When device 10 is in an unfolded configuration, the front and rear surfaces may be lie in parallel planes on opposing sides of device 10. Display 14 may be mounted in housing 12 on front surface F, whereas a planar rear housing wall in housing 12 forms rear surface R. In a folded configuration, portions of front surface F may face each other while portions of rear surface R may face away from each other. Alternatively, in the folded configuration, portions of rear surface R may face each other while portions of front portion F may face away from each other.

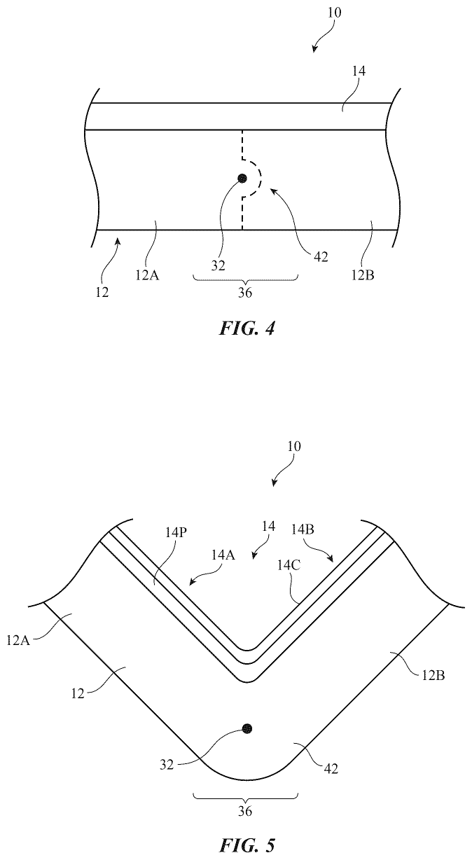

FIG. 4 is a side view of a portion of device 10 showing how display 14 may overlap a hinge in housing 12 such as hinge 42 at bendable region 36. Housing 12 may have first and second housing portions such as first housing portion 12A and second housing portion 12B (which may correspond to the left and right portions, respectively, of housing 12 discussed above in connection with FIG. 1). Hinge 42 runs along bend axis 32 and allows first housing portion 12A and second housing portion 12B to rotate relative to each other about bend axis 32, as shown in FIG. 5. Display 14 may include first display region 14A overlapping first housing portion 12A and second display region 14B overlapping second housing portion 12B. Display 14 may extend continuously across bend axis 32, if desired, so that images may be displayed uninterrupted across housing portions 12A and 12B.

Device 10 may, as an example, bend by 180° so that portions of housing 12 fold back on themselves. Hinge 42 may be configured to support other amounts of bending (e.g., more or less than 180° about axis 32), if desired. Hinge 42 may include rotating interlocking structures, may include multi-element linkages, may include flexible sheets of material that flex about axis 32 and therefore serve as hinge structures, may include accordioned and/or selectively thinned layers of material that promote flexing, and/or may include other suitable hinge structures that support rotation of portions of device 10 about axis 32.

Portions of display 14 may become hidden from view as device 10 is folded (e.g., when first and second halves or other portions of housing 12 rotate until they are adjacent to each other and overlap each other). Other portions of display 14 may be configured to remain exposed when device 10 is folded.

As shown in FIG. 5, display 14 may include display layers 14P that are overlapped by a display cover layer such as cover layer 14C. Display layers 14P may include a midplate (e.g., a structural member that supports the rest of display layers 14P), a force sensor, a back film (e.g., a metal back film), adhesives, an OLED layer (or an emissive layer of another suitable display technology), and/or any other suitable display layers.

Cover layer 14C may be a transparent cover layer with a high transparency (e.g., a transparency greater than 80%, greater than 90%, greater than 95%, greater than 99%, etc.). Cover layer 14C may have a thickness that is less than 200 microns, less than 100 microns, less than 50 microns, less than 30 microns, greater than 10 microns, greater than 20 microns, greater than 50 microns, between 20 microns and 90 microns, between 10 microns and 200 microns, etc.

Display cover layer 14C may be attached to display layers 14P using one or more optically clear adhesive layers, if desired. Display cover layer 14C may include one or more transparent layers of glass, polymer, sapphire, adhesive, and/or any other desired material. Display cover layer 14C may have a high transparency (e.g., greater than 80%, greater than 90%, greater than 95%, greater than 99%, etc.). Display cover layer 14C may have a thickness that is less than 200 microns, less than 100 microns, less than 50 microns, less than 30 microns, greater than 10 microns, greater than 20 microns, greater than 50 microns, between 20 microns and 90 microns, between 10 microns and 200 microns, etc.

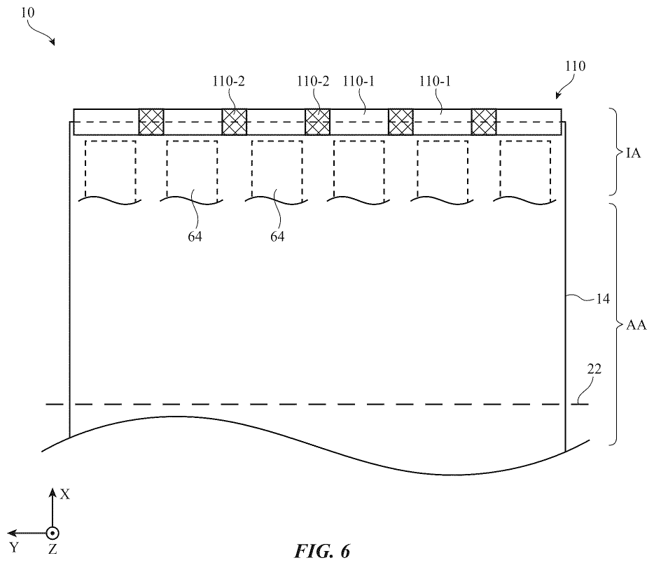

In some embodiments, cover layer 14C may be supported by underlying display layers (e.g., display layers 14P) that also extend into the inactive area. However, in other portions of the inactive area, display 14 may have display interconnects that wrap around an edge of the flexible display. In these panel bend portions, the underlying display layers may be blocked from extending into the inactive area due to the display interconnects. An illustrative example is shown in FIG. 6.

As shown in FIG. 6, display 14 may be formed from a display panel that is attached to flexible printed circuit(s) 64. For example, the display panel may be attached to multiple flexible printed circuits 64 (also referred to as display interconnects herein) along one or more edges of the display (e.g., the edges parallel to bend axis 32). The display panel, which may be formed from display layers (e.g., display layers 14P of FIG. 5) may be a flexible display panel that comprises an array of pixels. The display panel may have a portion that is attached to flexible printed circuits 64 at a bonding region. Flexible printed circuits 64 may be used to provide signals such as gate driver signals and/or data signals to the display panel (e.g., from a display driver integrated circuit and/or timing controller). As on example, a display driver integrated circuit (DDIC) may be mounted on flexible printed circuit 64 and may provide signals to the display panel via traces in flexible printed circuit 64. Flexible printed circuit 64 has a bent portion and wraps around the display panel.

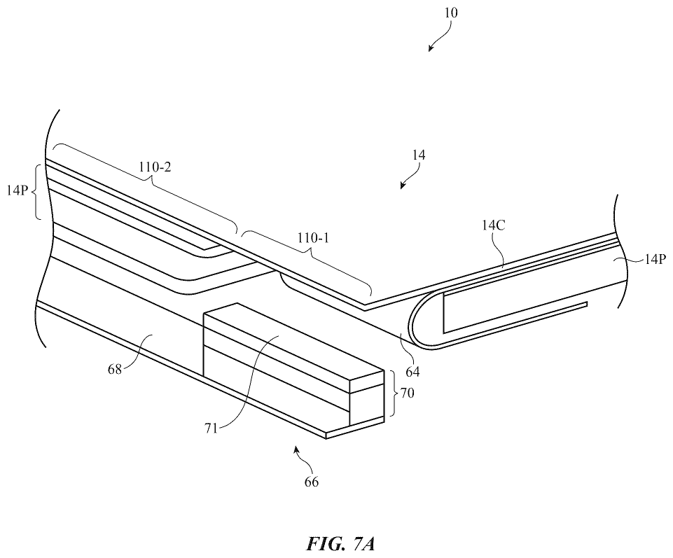

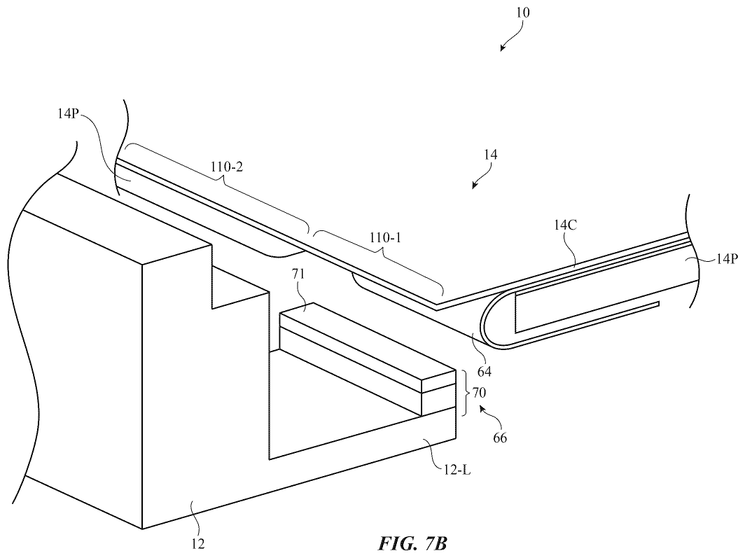

Edge portion 110 of display 14 in inactive area IA may include regions 110-1 that are aligned with printed circuits 64 and regions 110-2 that are interposed between regions 110-1. Although FIG. 6 shows edge portion 110 along a single edge of display 14, one or more peripheral edges of display 14 may include regions 110-1 and 110-2. In one example, the two edges of display 14 that are parallel to bend axis 32 may include regions 110-1 and 110-2. Alternatively, the two edges of display 14 that are orthogonal to bend axis 32 may include regions 110-1 and 110-2, or all four edges of display 14 may include regions 110-1 and 110-2. In regions 110-2, display layers (e.g., display layers 14P of FIG. 5) in display 14 may support cover layer 14C (FIG. 5) in edge portion 110. However, in regions 110-1, display layers in display 14 may be blocked from supporting cover layer 14C by printed circuits 64. Therefore, one or more endcaps may be used to support cover layer 14C in regions 110-1. An illustrative example of an endcap that may support a cover layer is shown in FIG. 7A.

As shown in FIG. 7A, display 14 of device 10 may include display layers 14P supporting display cover layer 14C in region 110-2. Display cover layer 14C may be, for example, a glass layer or a polymer layer that has a thickness of at least 30 microns, at least 50 microns, between 30 microns and 60 microns, at least 100 microns, 10 microns and 100 microns, at least 90 microns, less than 200 microns, or another suitable thickness. In general, display cover layer 14C may have any suitable thickness that protects display layers 14P while allowing device 10 (and display 14) to fold/bend. In other words, cover layer 14C may be a flexible cover layer.

The extension of display layers 14P in regions 110-2 may support display cover layer 14C in the inactive area of display 14. Display layers 14P may include a midplate (e.g., a structural member that supports the rest of display layers 14P), a force sensor, a back film (e.g., a metal back film), adhesives, an OLED layer (or an emissive layer of another suitable display technology), and/or any other suitable display layers.

However, due to the presence of printed circuit 64 doubling back on itself in region 110-1, display layers 14P cannot be extended from the active area of display 14 to the inactive area in regions 110-1. Therefore, endcap 66 may be added to support display cover layer 14C in region 110-1. Endcap 66 may include one or more layers 70 formed on (e.g., deposited on, adhesively attached to, or otherwise formed on) support 68.

Support 68, which may be formed from metal, polymer, or another suitable material, may be attached to a lowermost layer of display layers 14P in region 110-2. For example, the midplate of display layers 14P may be formed at the bottom of display layers 14P in region 110-2, and support 68 may be attached to the midplate. However, this is merely illustrative. In general, support 68 may be attached to any suitable layer within display layers 14P in region 110-2, a portion of housing 12 (FIG. 1), and/or another suitable portion of device 10. Support 68 may be attached to display layers 14P in region 110-2 using an adhesive, such as a pressure-sensitive adhesive (PSA), a gap-filling liquid adhesive, welding, and/or any other suitable attachment.

The one or more layers 70 of endcap 66 may include additional display layers, such as the same layers as display layers 14P. In other words, layers 70 may include a midplate (e.g., a structural member that supports the rest of display layers 14P), a force sensor, a back film (e.g., a metal back film), adhesives, an OLED layer (or an emissive layer of another suitable display technology), and/or any other suitable layers that are also included in display layers 14P in region 110-2. Put another way, layers 70 may include the same materials as display layers 14P. In this way, layers 70 may have the same properties, such as the same shear stiffness, as display layers 14P. By matching the shear stiffness of the overall display (e.g., by matching the shear stiffness of display layers 14P), endcap 66 may allow display 14 to translate during folding/unfolding, while supporting display cover layer 14C in regions 110-1. However, this is merely illustrative. In some embodiments, the one or more layers 70 may include one or more elastomer layers, polymer layers, and/or layers of another suitable material that matches (or is similar to) the properties of display layers 14P, such as the shear stiffness of display layers 14P. In other words, layers 70 may be formed from an elastomer with the same shear stiffness as display layers 14P.

Uppermost surface 71 of layers 70 may be attached to an inner surface of display cover layer 14C in region 110-1. For example, layers 70 may be attached to display cover layer 14C using an adhesive, such as a pressure-sensitive adhesive (PSA), a gap-filling liquid adhesive, and/or any other suitable attachment. In this way, display cover layer 14C may be supported by endcap 66 in region 110-1.

Although FIG. 7A shows a single region 110-2 and a single region 110-1, endcaps may support display cover layer 14C in any number of regions 110-1, such as all of the regions 110-1 or at least some of the regions 110-1 of FIG. 6. Endcaps in multiple regions 110-1 may be formed on a single support 68 or on separate supports, such as support 68.

Moreover, although FIG. 7A shows endcap 66 coupled to display layers 14P, this is merely illustrative. In some embodiments, endcap 66 may be coupled to a housing of device 10. An illustrative example is shown in FIG. 7B.

As shown in FIG. 7B, endcap 66, including layers 70 may be attached to housing 12. In particular, endcap 66 may be attached adhesively to housing 12, such as using pressure-sensitive adhesive (PSA), a gap-filling liquid adhesive, welding, and/or any other suitable attachment.

In the example of FIG. 7B, housing 12 has a ledge 12L to which endcap 66 is attached. However, this is merely illustrative. In general, endcap 66 may be attached to any suitable portion(s) of housing 12.

Although endcap 66 is shown in FIG. 7B as being adhesively attached to housing 12, this is merely illustrative. In some embodiments, a portion of housing 12 may form endcap 66. In other words, endcap 66 may be unified with housing 12 to form a unibody structure that supports cover layer 14C.

Regardless of whether endcap 66 is attached to display layers 14P (as shown in FIG. 7A) or to housing 12 (as shown in FIG. 7B), endcap 66 may be continuous or discontinuous. In other words, endcap 66 may be a single structure that supports cover layer 14C in multiple or all regions 110-1 and may therefore be continuous. Alternatively, device 10 may include multiple endcap 66 structures that each support one of regions 110-1, and endcaps 66 may therefore be discontinuous.

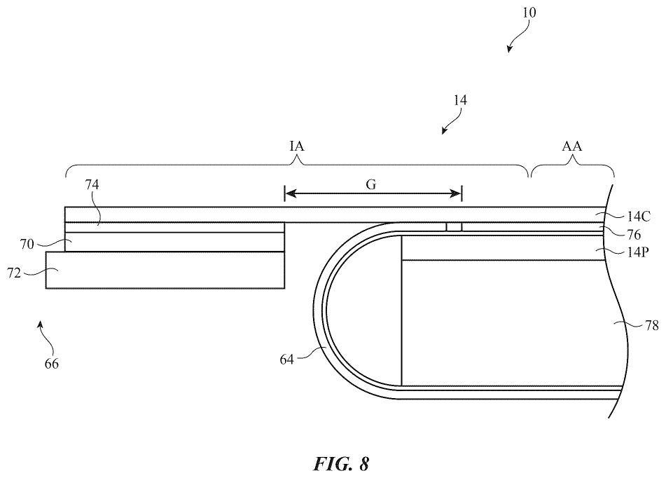

A side view of an illustrative device with an endcap is shown in FIG. 8. As shown in FIG. 8, display 14 may include display cover layer 14C that extends between active area AA (e.g., the region in which pixels in display 14 emit light to form images for a user of device 10) and inactive area IA. The portion of display 14 shown in FIG. 8 may correspond with one of regions 110-1 of FIGS. 6 and 7. In other words, display layers 14P may support cover layer 14C in active area AA and in a portion of inactive area IA. In particular, display layers 14P may be attached to cover layer 14C using adhesive 76, which may be a pressure-sensitive adhesive (PSA), a gap-filling liquid adhesive, and/or any other suitable attachment. Display layers 14P may be supported by one or more layers 78 that extend between display layers 14P and a rear portion of printed circuit 64. The one or more layers 78 may include support layers (e.g., midplate layers, such as metal or polymer midplate layers, adhesive layers, sensor layers, and/or any other suitable layers).

However, display layers 14P may be blocked by printed circuit 64 from support cover layer 14C in the remaining portion of inactive area IA within region 110-1. Therefore, endcap 66 may support cover layer 14C in the remaining portion of inactive area IA (e.g., in the portion of inactive area IA opposite printed circuit 64 from display layers 14P). Endcap 66 may include one or more layers 70 that are attached to cover layer 14C using adhesive 74, which may be a pressure-sensitive adhesive (PSA), a gap-filling liquid adhesive, and/or any other suitable attachment.

A bottom portion of layers 70 may be attached to support 72. Support 72 may be a metal layer, a polymer layer, or any other suitable layer that supports the one or more layers 70. For example, support 72 may be attached to support 68 of FIG. 7A, or support 72 may correspond with support 68 of FIG. 7A. Support 72 may alternatively or additionally be a portion of, or may be attached to a portion of, housing 12 (FIG. 3). In this way, cover layer 14C may be supported by endcap 66 in regions 110-1 of inactive area IA.

Endcap 66 may be separated from display layers 14P by gap G. Gap G may be less than 2 mm, less than 1.5 mm, between 1 mm and 2 mm, 1.7 mm, or another suitable distance. Gap G may be formed by the presence of printed circuit 64 and may be small enough to ensure that cover layer 14C is sufficiently supported by display layer 14P and endcap 66.

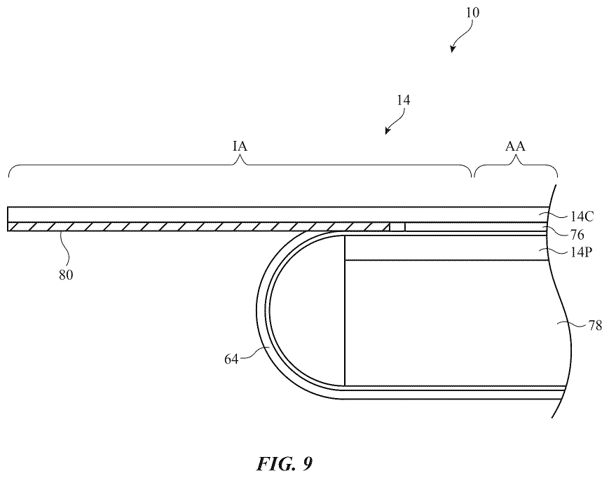

In addition to, or instead of, incorporating endcap 66 in regions 110-1 of inactive area IA, a stiffener may support cover layer 14C in regions 110-1. An illustrative example is shown in FIG. 9.

As shown in FIG. 9, stiffener 80 may extend across at least a portion of inactive area IA. The portion of display 14 shown in FIG. 8 may correspond with one of regions 110-1 of FIGS. 6 and 7. In other words, display layers 14P may support cover layer 14C in active area AA and in a portion of inactive area IA, while stiffener 80 may support cover layer 14C in the rest of inactive area IA. In some embodiments, however, stiffener 80 may extend across regions 110-1 and 110-2 of inactive area IA.

Stiffener 80 may be formed from a metal, such as steel (e.g., stainless steel, tungsten, titanium), carbon, carbon fiber, ceramic zirconia, diamond, borosilicate glass, another high-strength metal, a rigid polymer, an alloy, and/or any other suitable material. Stiffener 80 may have a Young's modulus that is greater than 50 GPa, greater than 100 GPa, greater than 200 GPa, greater than 400 GPa, greater than 800 GPa, greater than 1000 GPa, etc. In some embodiments, stiffener 80 may be formed from a rigid material, such as a metal, embedded in or otherwise incorporated with an opaque masking layer. In other words, because stiffener 80 is formed in inactive area IA, stiffener 80 may be opaque (e.g., stiffener 80 may not have to allow light from display layers 14P to pass).

The opaque masking layer may be formed from ink, a thin-film interference filter formed from dielectric layers with alternating refractive indexes, and/or any other suitable material. For example, the opaque masking layer may be a black masking layer and may hide inactive area IA, including printed circuit 64, from a user of device 10. The opaque masking layer (sometimes referred to as black masking layer) may have a low transparency (e.g., less than 30%, less than 20%, less than 10%, less than 5%, etc.). The opaque masking layer may extend in a ring around a periphery of display 14.

Stiffener 80 may be adhesively attached to cover layer 14C, may be formed on cover layer 14C (e.g., either directly formed on cover layer 14C or formed on a buffer layer on cover layer 14C), or otherwise attached to cover layer 14C. In this way, stiffener 80 may support cover layer 14C in regions 110-1 (and regions 110-2, if desired) of inactive area IA.

In some embodiments, an endcap (e.g., endcap 66 of FIG. 8) and stiffener 80 may be coupled to cover layer 14C in regions 110-1. Stiffener 80 may extend across gap G (FIG. 8) and provide additional support to cover layer 14C.

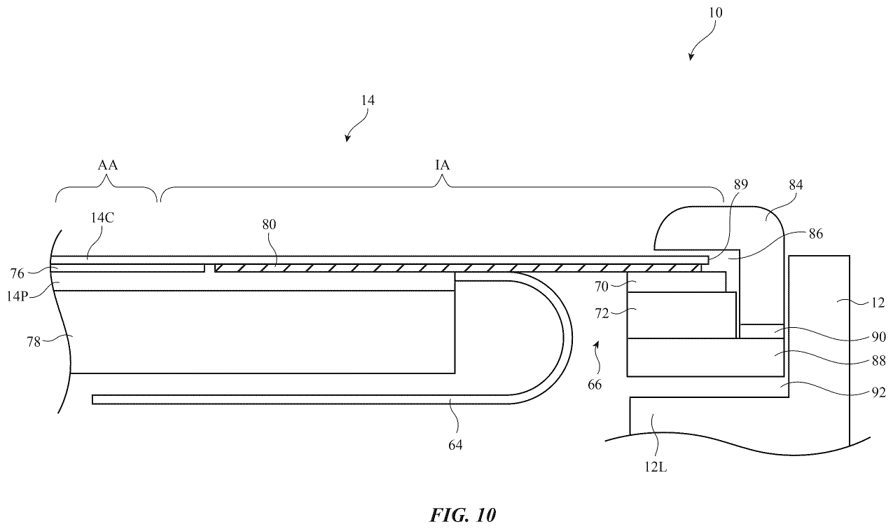

Regardless of whether an endcap, such as endcap 66, and/or a stiffener, such as stiffener 80, are used to support cover layer 14C in inactive area IA, the support structures may be coupled to housing 12 of device 10. An illustrative example is shown in FIG. 10.

As shown in FIG. 10. stiffener 80 and endcap 66 may support cover layer 14C in inactive area IA (e.g., in region 110-1 of inactive area IA). Additionally, trim 84 may overlap edge 89 of cover layer 14C and may be interposed between edge 89 of cover layer 14C and housing 12. In particular, trim 84 may be a polymer trim, an elastomer trim, a silicone trim, and/or any other suitable trim material. In some embodiments, trim 84 may be an opaque structure (e.g., a black structure) formed from compliant/compressible material, such as silicone. However, in some embodiments, trim 84 may include both compliant material and a stiff material, such as polycarbonate, polymer, metal, and/or other suitable stiff material.

Trim 84 may be separated from edge 89 of cover layer 14C by gap 86. Gap 86 may be at least 0.3 mm, at least 0.5 mm, between 0.25 mm and 0.75 mm, less than 1 mm, or another suitable sized gap. For example, gap 86 may be large enough to allow cover layer 14C to shift within gap 86 when display 14 is folded and unfolded.

Endcap 66 may be attached to support structure 88, which may be a metal layer, a polymer layer, or any other suitable support layer, such as using adhesive. Trim 84 may be attached to support structure 88 with adhesive 90, which may be a PSA, liquid adhesive, and/or any other suitable adhesive.

In the example of FIG. 10, support structure 88 is attached to ledge 12L using adhesive 92. Adhesive 92 may be a PSA, liquid adhesive, or other suitable adhesive. However, this is merely illustrative. In some embodiments, support structure 88 may be separated from ledge 12L and/or another portion of housing 12 by a gap.

Moreover, although support structure 88 is shown as being separate from support 72 and as being separate from housing 12, this is merely illustrative. In some embodiments, support structure 88 may be formed integrally with support 72. In other words, trim 84 may be attached directly to support 72. Alternatively support structure 88 may be formed integrally with housing 12.

By supporting cover layer 14C using stiffener 80 and endcap 66, cover layer 14C may be supported in inactive area IA (e.g., in region 110-1 of inactive area IA). Additionally, by using trim 84 to cover edge 89 of cover layer 14C and leave gap 86 between edge 89 and trim 84, cover layer 14C may shift when display 14 is folded and unfolded.

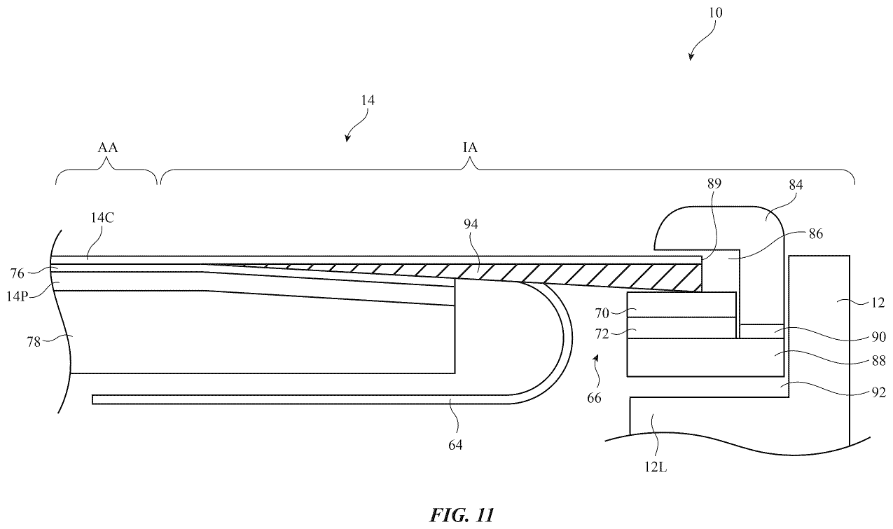

In the example of FIG. 10, stiffener 80 is a planar stiffener (e.g., a stiffener with a constant thickness). However, this is merely illustrative. In some embodiments, stiffener 80 may be a wedge-shaped stiffener that gradually increases in thickness between an edge of display layers 14P and endcap 66. An illustrative example is shown in FIG. 11.

As shown in FIG. 11, display 14 may include stiffener 94 between a lower surface of cover layer 14C and display layers 14P. Stiffener 94 may be a wedge-shaped stiffener with a first thickness between cover layer 14C and display layers 14P (e.g., adjacent to display layers 14P in active area AA) and a second thickness that is greater than the first thickness between cover layer 14C and endcap 66 (e.g., adjacent to endcap 66 at edge 89). The thickness may increase monotonically and continuously between the first thickness and the second thickness, or may increase in any other suitable manner between the first thickness and the second thickness.

Stiffener 94 may be formed from a metal, such as steel (e.g., stainless steel, tungsten, titanium), carbon, carbon fiber, silicon carbide, diamond, borosilicate glass, another high-strength metal, a rigid polymer, an alloy, and/or any other suitable material. Stiffener 94 may have a Young's modulus that is greater than 50 GPa, greater than 100 GPa, greater than 200 GPa, greater than 400 GPa, greater than 800 GPa, greater than 1000 GPa, etc. In some embodiments, stiffener 94 may be formed from a rigid material, such as a metal, embedded in or otherwise incorporated with an opaque masking layer. The opaque masking layer may be formed from ink, a thin-film interference filter formed from dielectric layers with alternating refractive indexes, and/or any other suitable material. For example, the opaque masking layer may be a black masking layer and may hide inactive area IA, including printed circuit 64, from a user of device 10.

Stiffener 94 may be adhesively attached to cover layer 14C, may be formed on cover layer 14C (e.g., either directly formed on cover layer 14C or formed on a buffer layer on cover layer 14C), or otherwise attached to cover layer 14C. In this way, stiffener 94 may support cover layer 14C in regions 110-1 of inactive area IA.

To accommodate wedge-shaped stiffener 94, display layers 14P may be bent downwards, and one or more layers 78 may be reduced in thickness (and/or reduced in the number of layers). If desired, one or more layers 70 of endcap 66 may be reduced in thickness to accommodate wedge-shaped stiffener 94.

In general, by increasing the thickness of stiffener 94 as stiffener 94 extends further from active area AA, stiffener 94 may provide additional support for cover layer 14C in inactive area IA (e.g., in region 110-1 of inactive area IA).

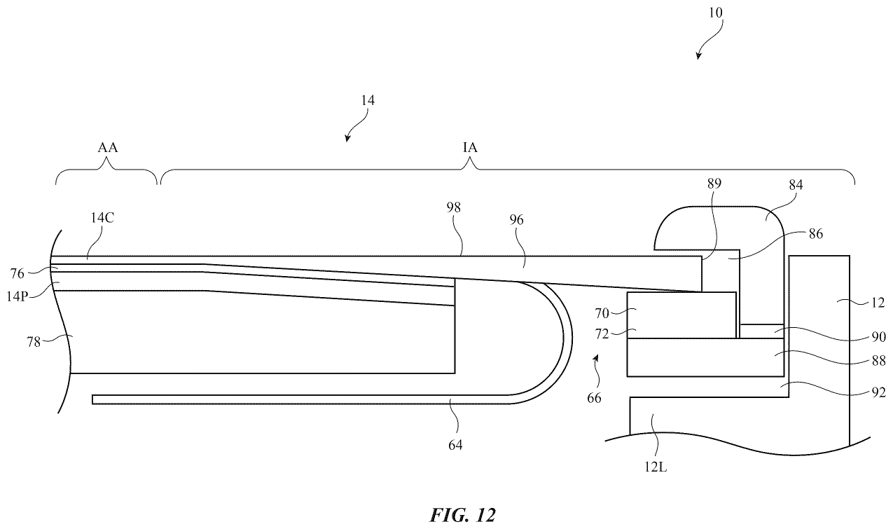

Instead of, or in addition to, including wedge-shaped stiffener 94 or stiffener 80, cover layer 14C itself may have increasing thickness in inactive area IA to strengthen cover layer 14C in inactive area IA. An illustrative example is shown in FIG. 12.

As shown in FIG. 12, cover layer 14C may have wedge-shaped region 96. In particular, wedge-shaped region 96 may increase in thickness as cover layer 14C extends from active area AA. Because wedge-shaped region 96 of cover layer 14C has a larger thickness than cover layer 14C in active area AA, cover layer 14C may have increased strength in inactive area IA.

Although not shown in FIG. 12, a stiffener, such as stiffener 80, may also be attached to an inner surface of cover layer 14C in inactive area IA, if desired.

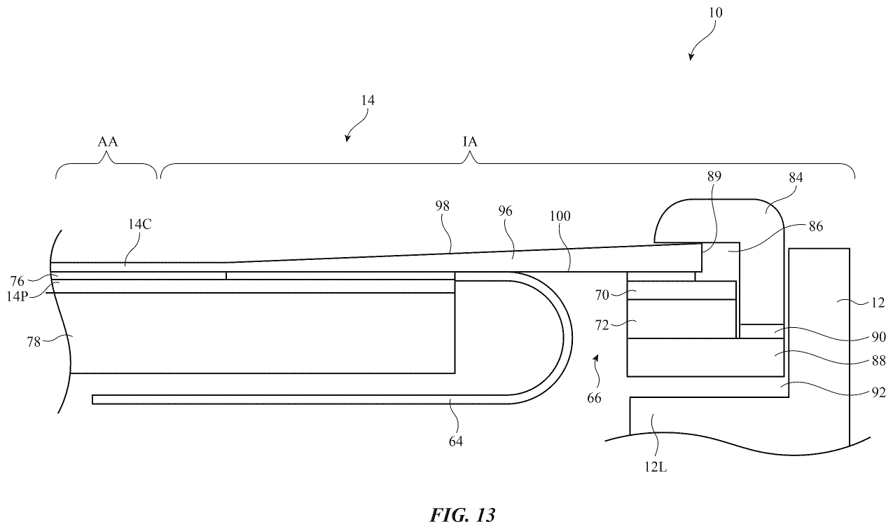

In the example of FIG. 12, wedge-shaped region 96 extends inwardly (e.g., toward the interior of device 10). In other words, exterior surface 98 of cover layer 14C may be planar across active area AA and inactive area IA. In some embodiments, however, cover layer 14C may have a wedge-shaped region that extends outwardly. An illustrative example is shown in FIG. 13.

As shown in FIG. 13, cover layer 14C may have wedge-shaped region 96 with planar interior surface 100 and angled exterior surface 98. Because wedge-shaped region 96 of cover layer 14C has a larger thickness than cover layer 14C in active area AA, cover layer 14C may have increased strength in inactive area IA.

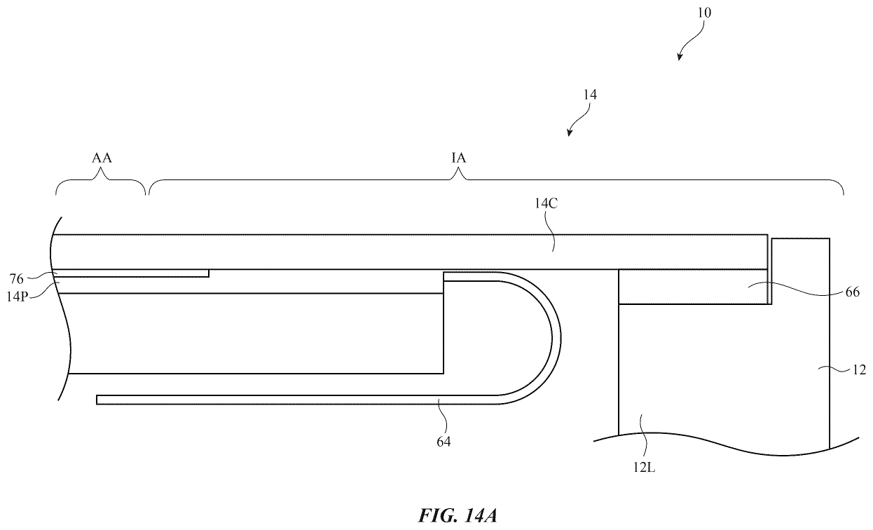

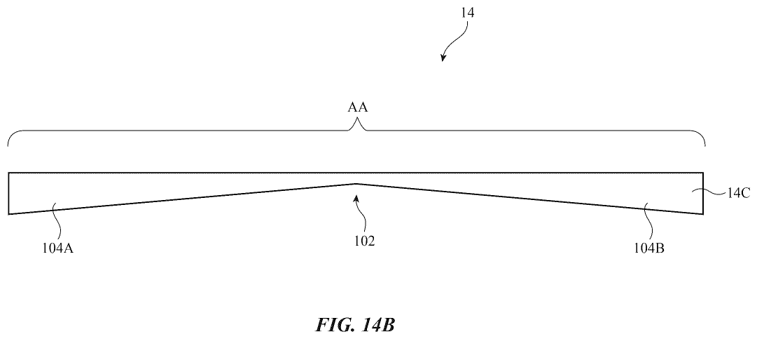

Although FIGS. 12 and 13 show the thickness of cover layer 14C increasing only in inactive area IA, this is merely illustrative. In some embodiments, the thickness of cover layer 14C may increase in active area AA and/or inactive area IA. An illustrative example is shown in FIGS. 14A and 14B.

As shown in FIG. 14A, cover layer 14C is planar with a constant thickness in inactive area IA. However, as shown in FIG. 14B, cover layer 14C may have increasing thickness in active area AA. In particular, cover layer 14C may have a minimum thickness at center 102, which may overlap bend axis 32 of device 10 (FIG. 1). Cover layer 14C may have wedge-shaped portions 104A and 104B that extend away from bend axis 32 with gradually increased thickness. Although FIG. 14A shows cover layer 14C having a constant thickness in inactive area IA, wedge-shaped portions 104A and 104B may continue to increase in thickness in inactive area IA, if desired.

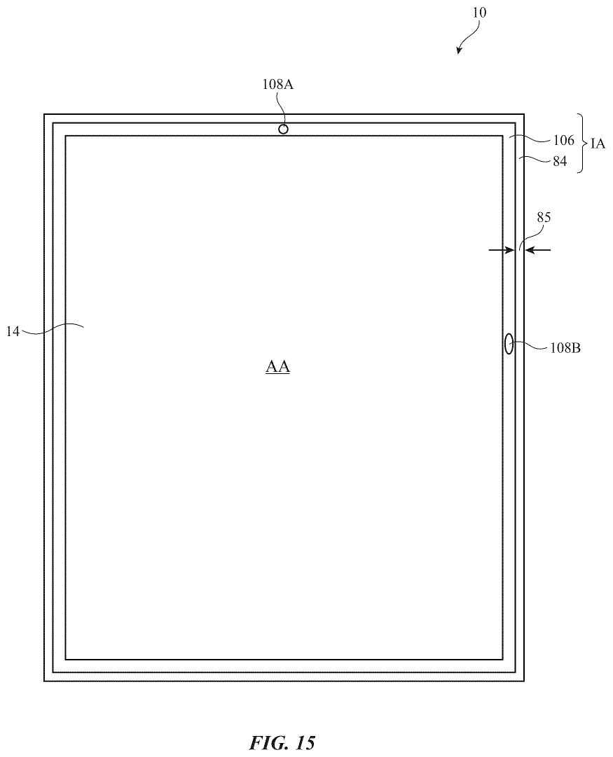

Due to the use of an endcap, such as endcap 66, and/or a stiffener, such as stiffener 60, wedge-shaped stiffener 94, or a cover layer with increased thickness, the size of trim 84 may be decreased. An illustrative example is shown in FIG. 15.

As shown in FIG. 15, display 14 may have active area AA and inactive area IA that extend around a periphery of active area AA (e.g., inactive area IA may surround active area AA). Inactive area IA may include opaque masking region 106, which may be formed from ink, a thin-film interference filter formed from dielectric layers with alternating refractive indexes, and/or other suitable opaque material. In general, opaque masking region 106 may hide underlying components, such as printed circuit 64 and a peripheral portion of display layers 14P (FIGS. 7-14) from view.

In some embodiments, a stiffener, such as stiffener 80 or stiffener 94 (FIGS. 9-11), may be included in opaque masking region 106. For example, the stiffener may extend entirely around the periphery of active area AA (e.g., the stiffener may be present along the entirety of opaque masking region 106). Alternatively, the stiffener may extend across a portion of opaque masking region 106, or the stiffener may be broken up into individual portions that together extend around the entirety of opaque masking region 106.

Trim 84 may extend around a periphery of opaque masking region 106 (e.g., trim 84 may surround opaque masking region 106). In other words, trim 84 may extend from opaque masking region 106 to edges of device 10.

Trim 84 may have width 85 (e.g., a width when looking at device 10 from the front). Width 85 may be less than 2 mm, less than 1.9 mm, between 1.5 mm and 2.5 mm, 1.8 mm, or another suitable width. In general, by supporting cover layer 14C using endcap 66 and/or a stiffener (FIGS. 6-14), the portion of inactive area IA covered by the cover layer (e.g., cover layer 14C) may be increased, which may reduce width that must be covered by a supplemental trim (e.g., trim 84).

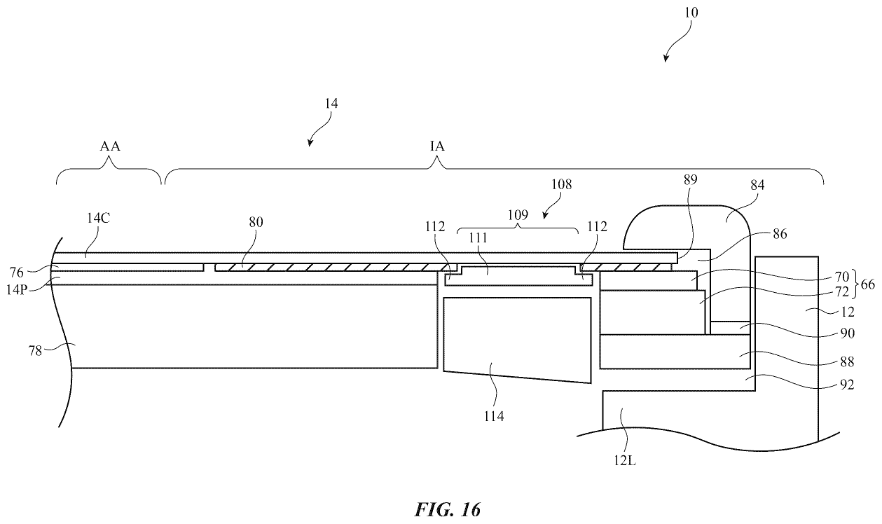

In some embodiments, it may be desirable to include optical components in inactive area IA. Therefore, windows, such as windows 108A and/or 108B, may be formed in opaque masking region 106. In the example of FIG. 15, windows 108 are shown along two edges of display 14. However, any suitable number of windows 108 may be formed along any suitable number of edges of display 14. An illustrative example of an optical component window is shown in FIG. 16.

As shown in FIG. 16, window 108 may be formed in inactive area IA. To accommodate window 108, opening 109 may be formed in stiffener 80. Opening 109 may be a circular opening (e.g., as shown by window 108A of FIG. 15), may be an elliptical opening (e.g., as shown by window 108B of FIG. 15), or may be an opening with any other suitable shape.

Lens 111 may be attached to stiffener 80 and extend across opening 109. Lens 111 may be, for example, a glass lens, a sapphire lens, a ceramic lens, an acrylic lens, or a lens of other suitable transparent material. Lens 111 may have flange 112, which may be a flange that extends around a periphery of lens 111. Flange 112 may be adhesively attached to stiffener 80 (e.g., around a periphery of opening 109), display layers 14P, and/or layers 70, such as using an optically clear adhesive (OCA). Alternatively or additionally, a central top surface of lens 111 may be adhesively attached to cover layer 14C, such as using OCA (in these embodiments, flange 112 may be kept or omitted from lens 111). In this way, lens 111 may be mounted within device 10.

Optical component 114 may operate through lens 111 and window 108. Optical component 114 may be a camera (e.g., a visible-light camera or an infrared camera), an ambient light sensor, a three-dimensional sensor (e.g., a three-dimensional camera), a light detection and ranging (LIDAR) sensor, or any other suitable optical component that emits and/or receives light through lens 111 and window 108. In general, if window 108 may be transparent to at least one wavelength of light (or at least one range of wavelengths) at which optical component 114 operates.

Although FIG. 16 shows lens 111 as a planar lens that overlaps optical component 114, this is merely illustrative. In some embodiments, lens 111 may be integrated with optical component 114, and optical component 114 and/or lens 111 may be attached to surrounding layers within electronic device 10 to maintain lens 111 within window 108. For example, optical component 114 may have a flange to adhesively attach component 114 to one or more surrounding layers.

The foregoing is merely illustrative and various modifications can be made to the described embodiments. The foregoing embodiments may be implemented individually or in any combination.

What is claimed is:

1. A display having an active area and an inactive area, the display comprising:
display layers in the active area;
a display cover layer that overlaps the display layers and that extends over the active area and the inactive area;
a stiffener coupled to the display cover layer in the inactive area; and
an endcap coupled to the display cover layer in the inactive area, wherein the endcap is separated from the display layers by a gap, and the stiffener extends across the gap.

2. The display of claim 1, wherein the display layers comprise first materials and the endcap comprises second materials that match the first materials of the display layers.

3. The display of claim 1, wherein the display layers have a first shear stiffness, and the endcap comprises an elastomer with a second shear stiffness that matches the first shear stiffness.

4. The display of claim 1, wherein the stiffener comprises a metal stiffener that is attached to the display cover layer.

5. The display of claim 4, wherein the metal stiffener has a constant thickness.

6. The display of claim 4, wherein the metal stiffener is a wedge-shaped stiffener with a first thickness adjacent to the display layers and a second thickness adjacent to the endcap, and the second thickness is greater than the first thickness.

7. The display of claim 1, wherein the stiffener extends from the display layers to the endcap across the gap.

8. The display of claim 1, wherein the stiffener has an opening in the inactive area to form an optical component window.

9. The display of claim 8, further comprising:
a lens that fills the opening in the stiffener.

10. The display of claim 9, wherein the lens comprises a flange, and the flange is adhesively attached to the stiffener around a periphery of the opening.

11. The display of claim 9, wherein the lens is adhesively attached to the display cover layer.

12. An electronic device, comprising:
a housing; and
a display in the housing, wherein the display has an active area and an inactive area, and the display comprises:
display layers,
printed circuits coupled to the display layers in first regions of the inactive area,
a display cover layer overlapping the display layers and the printed circuits, wherein the display layers are coupled to the display cover layer in second regions of the inactive area between the first regions, and
endcaps coupled to the display cover layer in the first regions.

13. The electronic device of claim 12, wherein the endcaps comprise supports that extend from the first regions to the second regions, and the supports are coupled to the display layers in the second regions.

14. The electronic device of claim 13, wherein the endcaps further comprise additional display layers that are separated from the display layers by a gap.

15. The electronic device of claim 12, further comprising:
trim that overlaps an edge of the display cover layer and that is interposed between the display cover layer and the housing.

16. The electronic device of claim 15, wherein the edge of the display cover layer is separated from the trim by a gap.

17. The electronic device of claim 15, further comprising:
a stiffener coupled to the display cover layer, wherein the stiffener extends from the display layers to the endcaps.

18. The electronic device of claim 15, wherein the display cover layer has a first thickness in the active area and has a second thickness that is larger than the first thickness at the edge.

19. The electronic device of claim 15, wherein the endcaps are coupled to the housing and are discontinuous.

20. The electronic device of claim 15, wherein the endcaps are coupled to the display layers.

21. An electronic device, comprising:
a housing;
a display in the housing, wherein the display has an active area and an inactive area, and the display comprises:
display layers in the active area,
a display cover layer that overlaps the display layers and that extends over the active area and the inactive area,
a stiffener coupled to the display cover layer in the inactive area, and
an endcap coupled to the display cover layer in the inactive area, wherein the endcap is separated from the display layers by a first gap; and
a trim interposed between an edge of the display cover layer and the housing, wherein the edge of the display cover is separated from the trim by a second gap.

22. The electronic device of claim 21, wherein the stiffener includes an opening forming a window, and the display further comprises a lens that fills the opening, the electronic device further comprising:
an optical component configured to operate through the lens.
